(19) United States
(12) Patent Application Publication
(10) Pub. No.: US 2008/0079149 A1
(43) Pub. Date: Apr. 3, 2008

(54) Circuit board arrangement and method for producing a circuit board arrangement

(76) Inventors: Harry Hedler, Germering (DE); Stephan Dobritz, Dresden (DE)

Correspondence Address: SLATER & MATSIL LLP, 17950 PRESTON ROAD, SUITE 1000, DALLAS, TX, 75252, US

(21) Appl. No.: 11/529,751

(22) Filed: Sep. 28, 2006

(51) Int. Cl. H01L 23/48

(52) U.S. Cl. 257/737

(57) ABSTRACT

A circuit board arrangement has a circuit board and a number of die elements, which are electrically conductively coupled to the circuit board by means of contacting elements. The die elements are arranged laterally partially overlapping one another on the circuit board, the contacting elements of the respective die elements being arranged next to one another.

### TECHNICAL FIELD

The invention relates to a circuit board arrangement comprising a circuit board with a number of die elements arranged thereon and a method for producing a circuit board arrangement.

### BACKGROUND

To meet the ever increasing demand for ever more powerful electronic devices, a significant major trend in the field of microelectronics consists, in particular, in providing ever smaller and ever lighter electronic components. Currently, it is attempted to achieve this by reducing the size of die elements, on the one hand and, on the other hand, increasing the packing density of die elements within a package. A typical answer for increasing the density of dies or chips consists in essentially providing dies which are stacked symmetrically on top of one another, in which in most cases the same connecting technology is used between the individual levels.

For memory modules, for example, an increase in the density of the dies is normally achieved by stacking dies next to one another within a package (MCP), stacking dies above one another (stacked CSP), or by package on package (POP), wherein the dies are required to be assembled on a module or supporting substrate for each of the said die packages. This leads to the die packages becoming wider and higher, on the one hand, and, on the other hand, the connections to the dies becoming longer which can lead to an increase in parasitic capacitances and, as a consequence, to erroneous signal transmissions. Furthermore, the said technology increases the complexity and the costs of die arrangements.

For these and other reasons, there is a need for the present invention as will be explained by means of the embodiments in the text which follows.

### SUMMARY OF THE INVENTION

According to an embodiment of the invention, a circuit board arrangement is provided which has a circuit board and a number of die elements. The die elements are electrically conductively coupled to the circuit board by means of contacting elements, the die elements being arranged laterally partially overlapping one another on the circuit board and the contacting elements of the respective die elements being arranged next to one another.

According to another embodiment, a method for producing a circuit board arrangement is provided, including arranging a number of die elements laterally partially overlapping one another on a circuit board, electrically conductively coupling the die elements to the circuit board by means of contacting elements, wherein the contacting elements of the respective die elements are arranged next to one another.

These and other features of the invention will become clearer from the description following by referring to the attached figures.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 shows a conventional circuit board arrangement with a number of die elements arranged thereon;

FIG. 2 shows an enlarged section of a conventional circuit board arrangement according to FIG. 1;

FIG. 3 shows a diagrammatic representation of a completed circuit board arrangement according to an embodiment of the invention;

FIGS. 4A to 4C in each case show a section of a circuit board arrangement according to an embodiment of the invention;

FIGS. 5A and 5B show a section of a circuit board arrangement according to an embodiment of the invention in cross section and in a top view;

FIGS. 6A and 6B show a section of a circuit board arrangement according to another embodiment of the invention in cross section and in a top view; and

FIG. 7 shows a diagrammatic representation of a completed circuit board arrangement according to an embodiment of the invention.

### DETAILED DESCRIPTION OF ILLUSTRATIVE EMBODIMENTS

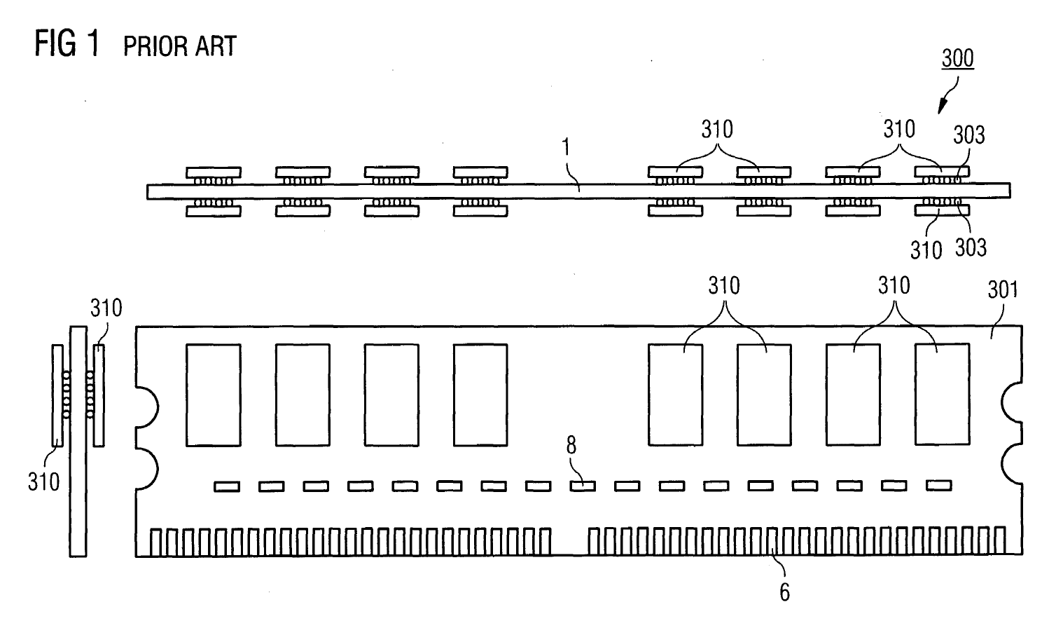

FIG. 1 shows a conventional circuit board arrangement 300 with a circuit board 301 having a contact strip 6, a number of die elements 310 arranged on the circuit board 301 and a number of passive electronic components 8 usually arranged on the circuit board 301 which can be, for example, ohmic resistors, capacitors, inductances or the like.

The die elements 310 arranged on both sides of the circuit board 301 are arranged in each case next to one another along the two component sides of the circuit board 301. The contacting elements 303 are formed on the side of the die elements 310 facing the circuit board 301. The contacting elements 303 can be solder balls or solder bumps, which are electrically conductively coupled to the circuit board 301. The conventional circuit board arrangement 300 according to FIG. 1 diagrammatically represents the configuration of a typical memory module.

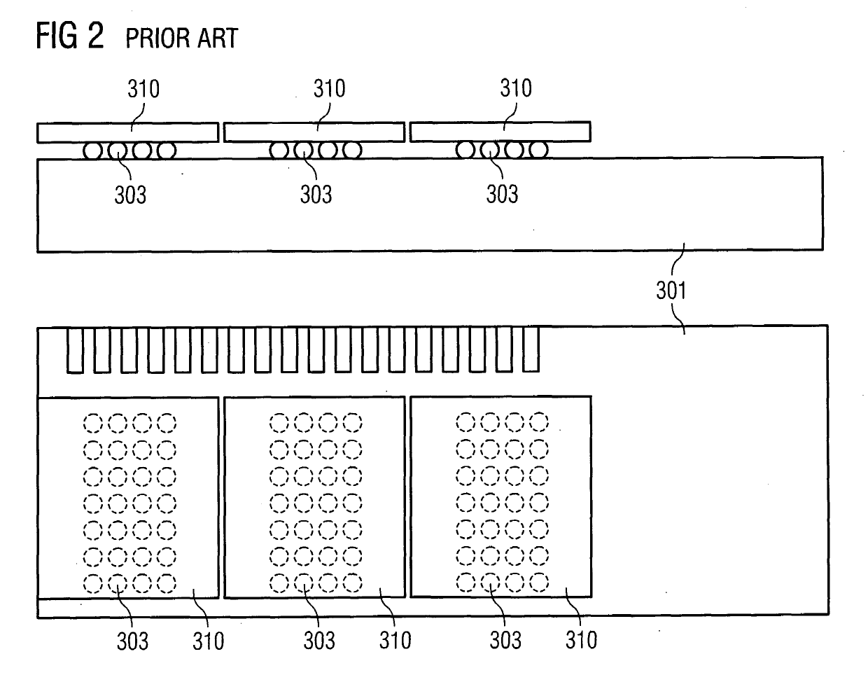

FIG. 2, in which an enlarged section from a conventional circuit board arrangement 300 according to FIG. 1 is shown, shows that the three die elements 310, shown by way of example, are arranged in one plane next to one another with a small space between them. The die elements 310 shown can be, for example, die elements which are orientated face down and which are produced at wafer level (WLPs) and are electrically coupled to the circuit board 301 with their contacting elements 303.

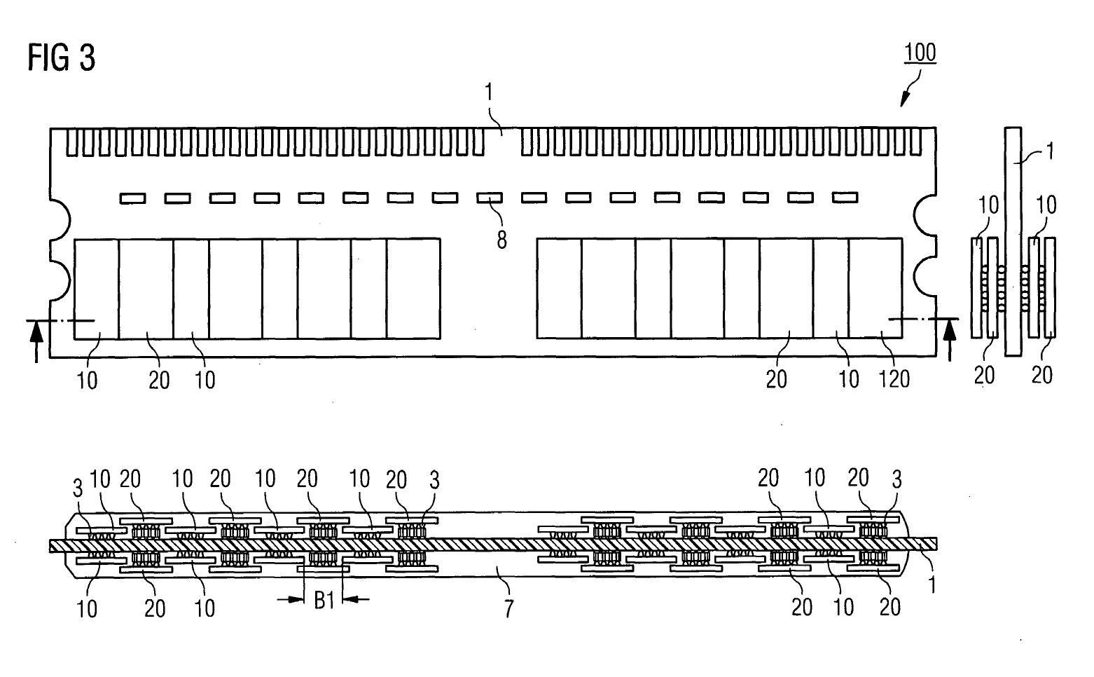

FIG. 3 shows a diagrammatic representation of a completed circuit board arrangement 100 according to an embodiment of the invention.

As can be seen from FIG. 3, the circuit board arrangement 100 exhibits a circuit board 1, which is conventional per se, on which, according to one embodiment, a number of die elements 10, 20 are arranged which at least partially overlap laterally, wherein the contacting elements 3 of the die elements 10, 20, by means of which the die elements 10, 20 are in each case electrically conductively connected to the circuit board 1, are arranged next to one another.

The die elements 10, 20 according to this embodiment are, for example, bare wafer-level packages (WLPs), that is to say bare die elements, which are produced at wafer level. These WLPs are, for example, die elements 10, 20, which are orientated face down and the bond pads of which are processed in the wafer sandwich with corresponding redistribution layers (RDLs) and have then been equipped with solder balls or solder bumps at the newly formed bond pads. In this manner, the contacting elements, that is to say the solder balls or solder bumps can be arranged on predefinable areas of the die element for example. Objectively, this means that the contacting elements can be arranged, for example either essentially in the center of the corresponding surface of the die element by leaving a circumferential edge free, or that the contacting elements can be arranged uniformly distributed otherwise on the remaining surface of the die elements 10, 20, for example by leaving a slightly wider edge area free. The die elements 10, 20 produced in this manner and arranged on the circuit board 1 have a thickness, for example, of less than or equal to approximately 100 μm.

As can be seen from the diagrammatic sectional view of FIG. 3, a number of die elements 10, 20 are in each case arranged, for example, on both component sides of the circuit board 1.

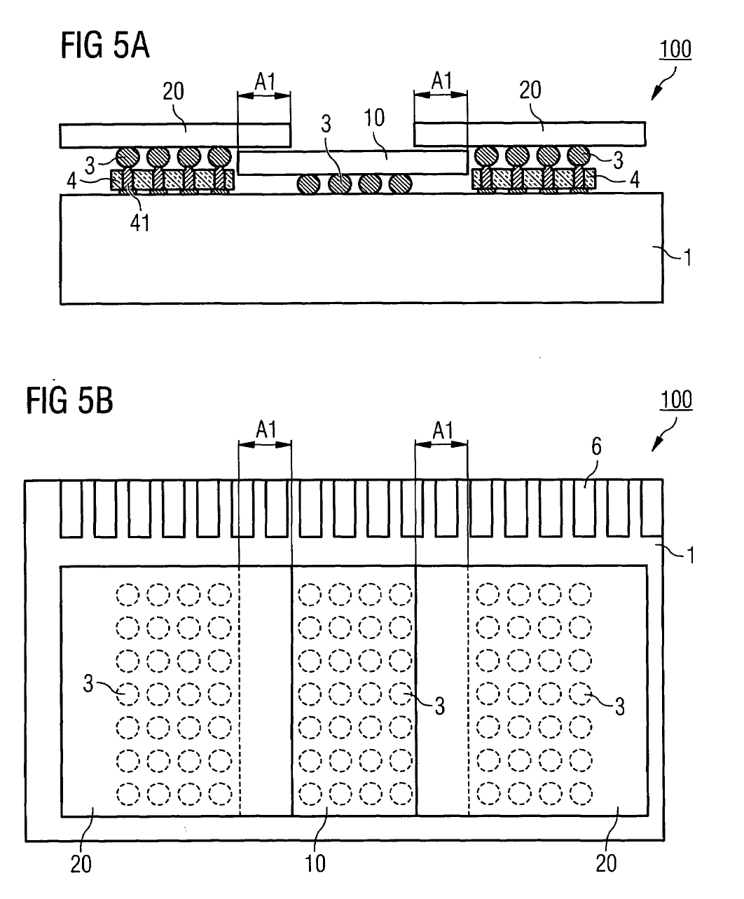

According to this embodiment, first die elements 10 are arranged in a first plane in each case with a predetermined space between them, the space B1, and are electrically conductively coupled to the circuit board 1 by means of contact elements3, also referred to herein sometimes as solder bumps 3 or solder balls, as the case may be. Above the first die elements 10 in a first plane, second die elements 20 are arranged in each case next to one another in a second plane. As can be seen from FIG. 3, the second die elements 20 can be arranged in each case in such a manner that second die elements 20 bridge a space B1 between two first die elements 10 and in each case overlaps one of the two first die elements 10 bounding the corresponding space B1 with in each case a lateral section A1 (compare FIG. 5A). It is only in the die element row in the second plane ending in each case on the right-hand side in the representation that one of the second die elements 20 can be arranged as conclusion in such a manner that it overlaps one of the first die elements 10 with only one lateral section A1. The contacting elements 3 of the die elements 20 arranged in the second plane which are in each case arranged next to the contacting elements 3 of the first die elements 10 will still be explained in greater detail with reference to another one of the figures.

As can also be seen from FIG. 3, the circuit board arrangement 100, according to an embodiment of the invention, can be covered, for example, with a mold layer 7 which is molded onto the circuit board 1 over its entire area at least in the area of the die elements 10, 20. Such a mold layer 7, which can also be arranged as cast package on the circuit board 1, provides mechanical protection for the die elements 10, 20 and the corresponding contacting elements 3 and also prevents the bare die elements 10, 20 and other electronic components 8 arranged on the circuit board 1 from being impaired in their functionality by, for example, dust or contamination from the later environment of the circuit board arrangement 100.

In an embodiment of the invention, a circuit board arrangement 100 is provided, which is equipped on each of its component sides with die elements 10, 20 arranged next to one another in two planes, wherein die elements 10, 20 arranged above one another in the two die planes are not in each case arranged in a common package by using a supporting substrate but are in each case coupled individually to the circuit board 1 as separate bare die elements 10, 20, which are offset with respect to one another in the longitudinal direction of the circuit board, having a thickness of, for example, less than or equal to approximately 100 μm, wherein the contacting elements 3 of the first die elements 10 of the first plane and the second die elements 20 of the second plane are in each case arranged next to one another.

In this manner, a circuit board arrangement having two rows of separate bare die elements can be provided which is distinguished by less complexity and is thus less expensive than, for example, a conventional circuit board arrangement in which the dual-die packages are used. Furthermore, the circuit board arrangement 100, in spite of the arrangement of die elements 10, 20 in two planes per component side, has a thickness which meets the requirements for ever smaller modules due to the use of, for example, bare thin die elements 10, 20. The circuit board arrangement 100 according to the illustrative embodiment explained by means of FIG. 3 can be, for example, a memory module 1.

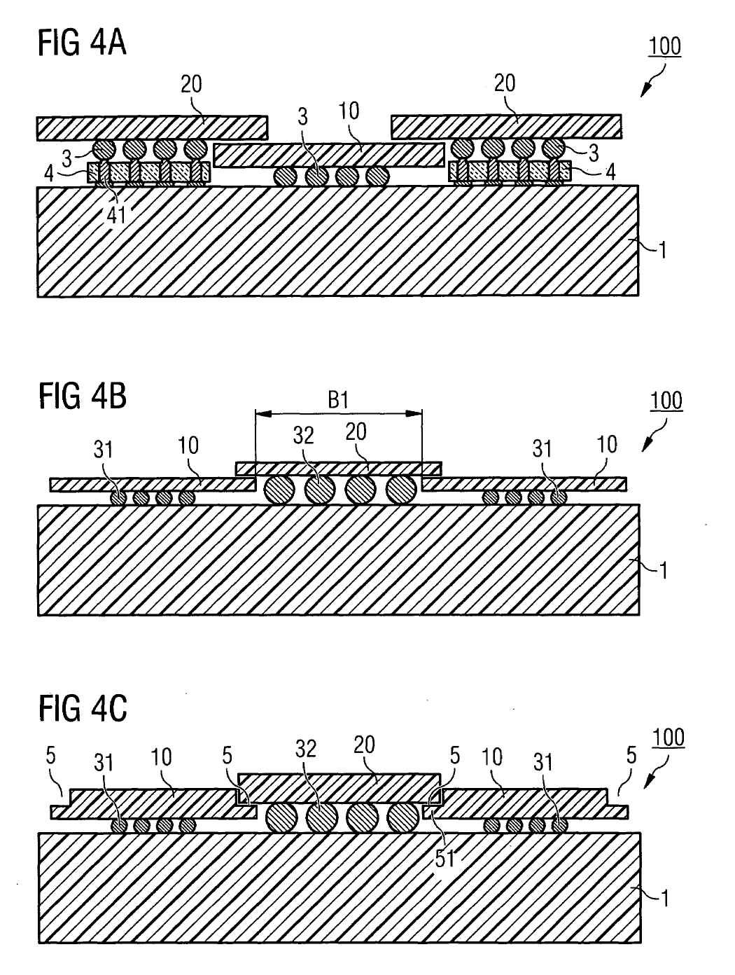

FIGS. 4A to 4C in each case show a section of a circuit board arrangement 100 according to an embodiment of the invention.

In the embodiment according to FIG. 4A, too, first die elements 10 are arranged in a first plane and second die elements 20 are arranged in a second plane on the component sides of the circuit board 1 (only one component side is shown).

Both the first die elements 10 and the second die elements 20 have as contacting elements, for example, solder balls 3 which can be formed of essentially the same size and in an identical grid pattern in all die elements 10, 20 so that, for example, identically constructed die elements 10, 20 can be used overall for the circuit board arrangement. The contacting elements 3 of the first die elements 10 in the first die plane can be electrically connected directly to the circuit board 1 with corresponding connections (not shown).

To be able to bring the contacting elements 3 of the die elements 20 into electrically conductive contact with the circuit board 1, interconnect PCB sections 4 are inserted between the second die elements 20 of the second die plane and the surface of the circuit board 1 according to one embodiment, by means of which the space between the die elements 20 and the circuit board 1, which is determined by the thickness of the die elements 10 on which the die elements 20 are supported, can be bridged. The interconnect PCB sections 4 have at positions corresponding to the contact elements 3 suitable through-contacting means 41 so that an electrically conductive connection between the die elements 20 and the circuit board 1 is made possible. Suitable through-contacting means 41 can be formed, for example, by conductive paste accommodated in through holes or by line sections accommodated in through holes.

As an alternative to the arrangement of the interconnect PCB sections 4, the circuit board 1 can have, for example, raised sections in the manner of a relief (not shown) on its surface which can correspond to the interconnect PCB sections 4 in their position and dimension. The sections raised in the manner of a relief have on their top the corresponding connections by means of which the contact elements 3 of the second die elements 20 can be electrically conductively connected. The second die elements 20 can have contact elements 3 which are similar to those of the die elements 10 also in this embodiment.

FIG. 4B shows a further embodiment of the invention with a circuit board 1 and the die elements 10, 20 arranged in two planes, the die elements 10, 20 laterally overlapping at least partially. As can be seen from FIG. 4B, the second die elements 20 have contact elements 32, for example in the form of solder balls, the size of which differs from the solder balls 31 of the first die elements 10. By using correspondingly dimensioned contact elements 32 (solder balls), the space between the second die elements 20 and the surface of the circuit board 1, which is level in this case, is overcome according to this embodiment. This arrangement can be advantageous if, for example, particularly thin die elements 10, 20 are used for the circuit board arrangement 100. As already stated, this can be, for example, WLPs with a thickness of less than or equal to approximately 100 μm.

According to FIG. 4C, a section of a circuit board arrangement 100, according to yet another embodiment, is shown in which the first die elements 10 have in their edge regions, in which they are overlapped by second die elements 20, in each case recesses 5 extending over the entire length or width, respectively. In this manner, it is possible to insert in each case one of the second die elements 20, bridging the space B1 between two first die elements 10, with its side edges into the recesses 5 of the corresponding two first die elements 10 and thus to reduce the space between the active side of the second die element 20, aligned face down, and the top of the circuit board 1, by a greater amount than when the second die element 20 is supported on the top of the first die elements 10 as shown in FIG. 4A.

Since, due to the recesses 5, the space between the die elements 20 and the top of the circuit board 1 is less in this embodiment than that according to the embodiment in FIG. 4A and approximately corresponds to the space between the second die elements 20 and the top of the circuit board 1 according to the embodiment in FIG. 4B. According to the embodiment in FIG. 4B, the die elements are constructed to be particularly thin, for example, the formation of raised parts on the circuit board 1 or the arranging of interconnect PCB sections 4 (FIG. 4A) can be omitted in this circuit board arrangement so that, instead, for example, only solder balls 32, which are slightly larger than the solder balls of the first die elements 10 can be used as contact elements. Such recesses 5 can be made on the die elements 10 without problems since the relevant edge areas are free of circuits (not shown) for safety reasons and furthermore the circuits are only constructed, for example, in a thinner substrate layer facing the circuit board 1 which is not affected by the recesses 5, in any case.

The recesses 5 on the die elements 10 can be produced, for example, during the dicing by sawing into the die on both sides of the dicing channel so that a separate process for forming the recesses 5 can be avoided in the production of the die elements.

If, for example, other elements than WLPs are used as die elements 20, recesses 5, which are, for example, complementary to the recesses in the die elements 10, can be provided also on the other die elements 20 arranged in the second plane in addition to the die elements 10, so that, for example, the die elements of the second plane can be arranged with their lateral sections formed offset towards the top by means of the recess in the area of the lateral sections 51 of the die elements 10 which are formed by means of the recesses 5.

FIGS. 5A and 5B show a section of a circuit board arrangement according to an embodiment of the invention in cross section and in a top view.

In FIG. 5A, an embodiment of a circuit board arrangement 100 is again shown which essentially corresponds to the embodiment of a circuit board arrangement 100 explained with reference to FIG. 4A.

As can be seen, the first die elements 10 arranged in the first plane (only one die element is shown) are in each case overlapped on both sides by a second die element 20 arranged in a second plane with a section A1 in the area of which no contact elements are provided. In this circuit board arrangement 100, the first die elements 10, for example, also have their contacting elements 3 only outside the areas A1. However, it is also possible that other die elements than the die elements 10 shown can be used for the circuit board arrangement which, for example, can also have contacting elements 3 underneath the overlapping sections A1.

From the top view of a section from the circuit board arrangement 100 according to FIG. 5B it can be seen that the first die elements 10 and the second die elements 20 have symmetrically arranged contact elements, for example in the form of solder balls 3.

Furthermore, a comparison of the representations of the circuit board arrangement 100 according to FIG. 5B and the conventional circuit board arrangement 300 according to FIG. 1 will show that for the arrangement of, for example, three die elements in the form of WLPs according to one embodiment of the invention, only approximately 84% of the area of the circuit board 1 is used up which is needed for the conventional arrangement of three die elements in the form of WLPs in a conventional circuit board arrangement 300.

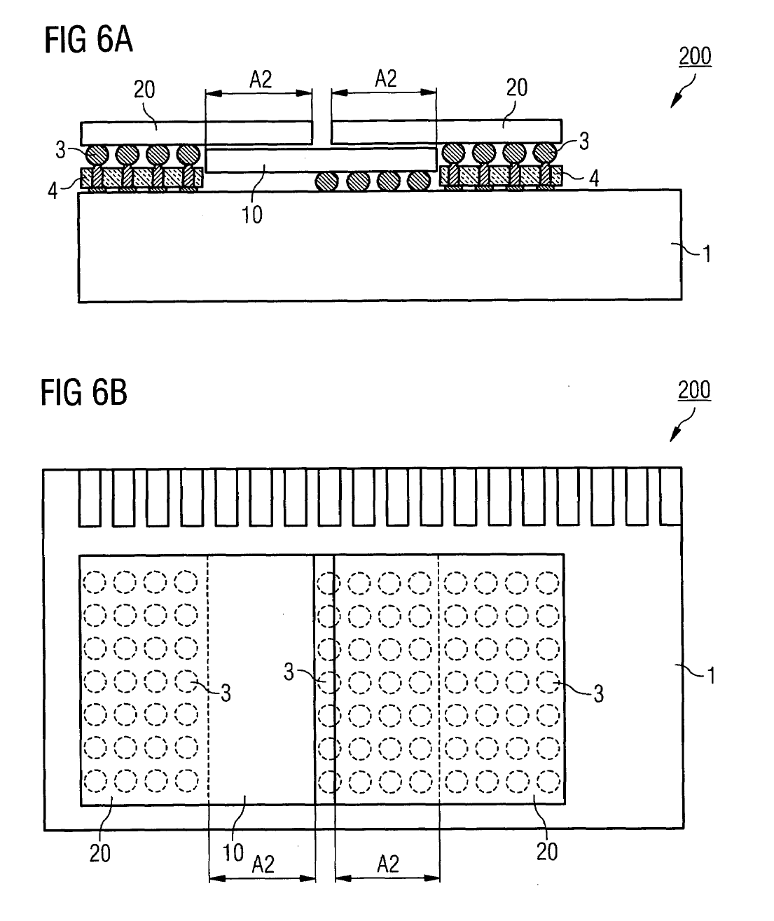

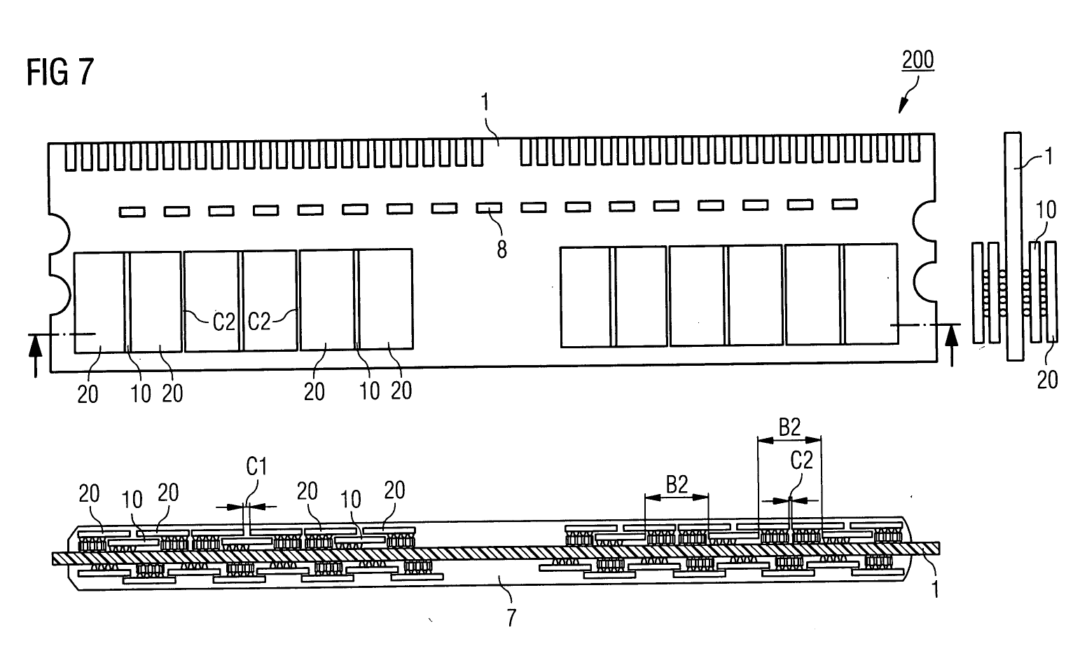

FIGS. 6A and 6B show a section of a circuit board arrangement according to another embodiment of the invention in cross section and in a top view and FIG. 7 shows a diagrammatic representation of a completed circuit board arrangement according to an embodiment of the invention.

As can be seen, in particular, from FIG. 6A and the lower representation in FIG. 7, first die elements 10 having in each case a space B2 between them are arranged next to one another in a first plane on the circuit board 1 in the circuit board arrangement 200 according to one embodiment. Second die elements 20 are arranged in a second plane over the first die elements 10 in each case closely next to one another with only a small space C1 and C2, respectively, between them. The first and second die elements 10 and 20 shown can be, for example, WLPs, the contact elements 3 of which, which are, for example, solder balls, are in each case asymmetrically arranged. Objectively, this means that the contact elements 3 are in each case arranged, for example, only on about half the base area of the die element 10, 20. Such an arrangement can be formed as standard, for example during the processing of an RDL.

According to this embodiment shown, two second die elements 20 and one first die element 10 in each case form a group of die elements. Several such groups of die elements are arranged next to one another on both component sides along the circuit board 1 (even though they are shown only one component side in FIG. 7).

As can be seen from FIGS. 6A, 6B and 7, the first die element 10 of each one of the die element groups is overlapped from its two sides by in each case one die element 20 with a first section A2 which does not have any contacting elements 3, the other section of which (apart from the die element groups which are arranged in the edge area of the circuit board 1) partially reaches across an intermediate space B2 between two first die elements 10 so that the contacting elements 3 arranged on the second section of the second die element 20 can be electrically coupled to the section of the circuit board 1 lying underneath. Although in each case one interconnect PCB section 4 is in each case arranged between the two die elements 20 and the circuit board 1 for bridging the space between in FIG. 6A, larger solder balls, as shown, for example, in FIG. 4B, can also be used instead as contacting elements for the second die elements 20 when the die elements 10, 20 are, for example, constructed to be correspondingly thin, and correspondingly smaller solder balls are arranged for connecting the die elements 10, for example.

In an embodiment of the circuit board 200 with die elements 20, the contacting elements 3 are arranged asymmetrically, the die elements 20 can be arranged essentially closely next to one another in the upper, that is to say the second die plane, and additionally, first die elements 10 can be arranged in a first plane as a result of which a distinctly higher packing density of, for example, WLPs can be achieved than is possible with a conventional circuit board arrangement 300 with WLPs (compare FIG. 1). Since the WLPs used, for example, are bare die elements, a more powerful circuit board arrangement 200 can be achieved without excessively increasing the thickness of the circuit board arrangement 200 then completed. As can also be seen from FIG. 7 (bottom), the circuit board arrangement 200 can also be covered, according to one embodiment of the invention, for example, with a mould layer 7 in which at least the, for example, bare die elements 10, 20 and contacting elements 3 and the remaining electronic components 8 are molded in so that a good mechanical protection is provided for the die elements 10, 20 by the mold layer.

In a comparison of the representations of the circuit board arrangement 200 according to FIG. 6B and the conventional circuit board arrangement 300 according to FIG. 1, it can also be seen that for arranging, for example, three die elements in the form of WLPs according to one embodiment of the invention, in which the die elements 10, 20 are provided with asymmetrically arranged contact elements 3, only about 68% of the area on the circuit board 1 is used up which is needed for the conventional arrangement of three die elements in the form of WLPs in a conventional circuit board arrangement 300. The circuit board arrangements 100 and 200 can be constructed, for example, as memory modules.

In each of the said embodiments of the circuit board arrangement, in consequence, the individual die elements are not arranged above one another in such a manner that their side edges are flush with one another but are arranged, for example, in two rows or planes, in each case in such a manner that the die elements in the upper die plane are in each case laterally offset with respect to the die elements in the lower plane, two of the possible ways of stacking having been shown by way of example by means of the embodiments according to FIGS. 5 and 6.

According to one embodiment of the invention, a circuit board arrangement is provided which has a circuit board and a number of die elements which are electrically conductively coupled to the circuit board by means of contacting elements, wherein the die elements are arranged laterally partially overlapping one another on the circuit board and the contacting elements of the respective die elements are arranged next to one another.

The contacting elements arranged at the die elements can have solder bumps or solder balls.

Along the circuit board, first die elements can be arranged in a first plane in each case next to one another with a space between them and above the first die elements, second die elements can be arranged next to one another in a second plane, wherein each of the second die elements partially overlaps at least one of the first die elements with at least one section and at least partially reaches across the corresponding space adjoining the first die element with another section.

According to one embodiment of the circuit board arrangement, one of the second die elements is in each case arranged bridging a space between in each case two first die elements.

Above each of the first die elements, two second die elements can be arranged next to one another in such a manner that each of the two second die elements partially overlaps the first die element with in each case one first section and partially reaches across a respective space formed next to the first die element with in each case a second section.

At least one die element of two laterally partially overlapping die elements can have at its overlapping section a recess, which is engaged by the other one of the two die elements with its overlapping section.

According to one embodiment, the die elements can have at their respective laterally overlapping sections in each case recesses, which are formed complementary to one another so that the lateral section of the one die element, which is formed by means of the recess, engages the recess of the respective other die element.

The contacting elements of the second die elements are in each case arranged at a section of the second die elements, which is free of overlap.

The contacting elements may consist of solder bumps, solder balls, copper pillar bumps or similar electrically conductive bumps, wherein the contacting elements of the second die elements arranged in the second plane can be constructed to be larger than the contacting elements of the first die elements arranged in the first plane.

The circuit board of the circuit board arrangement can be constructed to be raised at least in the area of the sections of the second die elements, which are free of overlap.

The contacting elements of the first and of the second die elements, which are arranged next to one another on the circuit board can have solder bumps or solder balls, which are essentially constructed to be of the same size.

According to one embodiment, interconnect PCB sections can be arranged between the circuit board and at least the sections of the second die elements, which are free of overlap.

The die elements can be bare wafer-level packages (W-CSPs, WLPs).

The die elements can be dies, which are orientated face down.

The die elements can have a thickness of less than or equal to approximately 300 μm, e.g. a thickness of less than or equal to approximately 100 μm.

The die elements can have memory cells.

The circuit board of the circuit board arrangement can be equipped with die elements on both sides.

At least the area of the circuit board having the die elements can be covered with a mold layer.

According to one embodiment of the invention, a method for producing a circuit board arrangement can have the following:

arranging a number of die elements at least partially overlapping one another laterally on a circuit board,

electrically conductively coupling the die elements to the circuit board by means of contacting elements, wherein the contacting elements of the respective die elements are arranged next to one another.

What is claimed is:

1. A circuit board arrangement, comprising:
a circuit board and a plurality of die elements which are electrically conductively coupled to the circuit board by means of contacting elements; and
wherein the die elements are arranged laterally partially overlapping one another on the circuit board and the contacting elements of the respective die elements are arranged next to one another.

2. The circuit board arrangement according to claim 1, wherein the contacting elements of the die elements comprise electrically conductive bumps.

3. The circuit board arrangement according to claim 2, wherein the contacting elements of the die elements comprise solder bumps, solder balls or copper pillar bumps.

4. The circuit board arrangement according to claim 1, wherein:
a first plurality of die elements are arranged next to one another in a first plane along the circuit board with a space between adjacent ones of the first plurality of die elements;
a second plurality of die elements arranged next to one another in a second plane above the first plane; and
wherein each of the second plurality of die elements partially overlaps at least one of the first plurality of die elements and respective ones of the second plurality of die elements at least partially overlap corresponding spaces between respective ones of the first plurality of die elements.

5. The circuit board arrangement according to claim 4, wherein each one of the second plurality of die elements bridges a space between a respective two of the first plurality of die elements.

6. The circuit board arrangement according to claim 4,wherein above each of the first plurality of die elements, two of the second plurality of die elements are arranged next to one another in such a manner that a respective first section of each of the two of the second plurality of die elements partially overlaps the respective one of the first plurality of die elements and a respective section of each of the two of the second plurality of die elements partially extends across a respective space formed next to the respective one of the first plurality of die elements.

7. The circuit board arrangement according to claim 1, wherein at least one die element of two laterally partially overlapping die elements has at its overlapped section a recess which is engaged by the other one of the two die elements with its respective overlapped section.

8. The circuit board arrangement according to claim 1, wherein each die element has a recess at its respective laterally overlapping section which is shaped complementary to another recess of another die element so that the laterally overlapping section of one die element formed by means of the recess engages the recess of the respective another die element.

9. The circuit board arrangement according to claim 4, wherein the respective contacting elements of the second plurality of die elements are arranged at a section of the respective second plurality of die elements that is free of overlap with another die element.

10. The circuit board arrangement according to claim 4, wherein the contacting elements comprise solder bumps or solder balls and the contacting elements of the second plurality of die elements are larger than the contacting elements of the first plurality of die elements.

11. The circuit board arrangement according to claim 4, wherein the circuit board is constructed to be raised at least in a area of sections of the second plurality of die elements free of overlap.

12. The circuit board arrangement according to claim 10, wherein the contacting elements, arranged next to one another, of the first and of the second plurality of die elements comprise electrically conductive bumps.

13. The circuit board arrangement according to claim 4, wherein the contacting elements, arranged next to one another, of the first and of the second plurality of die elements comprise solder bumps, solder balls or copper pillar bumps which are essentially of the same size.

14. The circuit board arrangement according to claim 4, further comprising interconnect PCB sections arranged between the circuit board and at least the sections of the second plurality of die elements that are free of overlap.

15. The circuit board arrangement according to claim 1, wherein the die elements are bare wafer level packages.

16. The circuit board arrangement according to claim 1, wherein the die elements are dies which are orientated face down.

17. The circuit board arrangement according to claim 1, wherein the respective die elements have a thickness of less than or equal to approximately 100 μm.

18. The circuit board arrangement according to claim 1, wherein at least one of the die elements comprises memory cells.

19. The circuit board arrangement according to claim 1, wherein the circuit board is equipped with the die elements on both sides.

20. The circuit board arrangement according to claim 1, wherein at least the area of the circuit board having the die elements is covered with a mould layer.

21. A method for manufacturing a circuit board arrangement, comprising:
arranging a plurality of die elements laterally partially overlapping one another on a circuit board; and
electrically conductively coupling the die elements to the circuit board by means of contacting elements, wherein the contacting elements of the respective die elements are arranged next to one-another.
